(19) United States
(12) Patent Application Publication
(10) Pub. No.: US 2025/0287712 A1
(43) Pub. Date: Sep. 11, 2025

(54) SOLID-STATE IMAGING DEVICE

(71) Applicant: Samsung Electronics Co., Ltd., Suwon-si (KR)

(72) Inventor: Kazufumi Shiozawa, Yokohama (JP)

(21) Appl. No.: 19/025,015

(22) Filed: Jan. 16, 2025

(30) Foreign Application Priority Data
Mar. 5, 2024 (JP) 2024-032693

(51) Int. Cl. H10F 39/00

(52) U.S. Cl. CPC H10F 39/8063; H10F 39/804; H10F 39/8067; H10F 39/811

(57) ABSTRACT

Provided is a solid-state imaging device that enables reduction of color mixing and improvement of light absorbency in a photoelectric conversion unit. A pixel includes a first periodic structure, the first periodic structure includes a plurality of first layers and a plurality of second layers having a lower refractive index than that of the first layers, and in at least one of a plurality of pixels, the first layers and the second layers of the first periodic structure are arranged such that, in a pixel central portion in the horizontal direction, the volume proportions of the first layers in the horizontal direction are greater than the volume proportions of the second layers, and the volume proportions of the first layers decrease from the pixel central portion toward a pixel peripheral portion in the horizontal direction.

### CROSS-REFERENCE TO RELATED APPLICATION

This application claims priority under 35 U.S.C. § 119 to Japanese Patent Application No. 2024-032693, filed on Mar. 5, 2024, in the Japan Patent Office, the disclosure of which is incorporated by reference herein in its entirety.

### BACKGROUND

The inventive concept relates to a solid-state imaging device.

Solid-state imaging devices are installed in various mobile terminals such as digital cameras or mobile phones.

Referring to Japanese Patent Publication No. 2022-108744, a solid-state imaging device includes a photoelectric conversion unit configured to generate and accumulate electric charges according to the amount of incident light, an on-chip lens installed on one side of the photoelectric conversion unit where light is incident, and a wiring layer installed on the other side of the photoelectric conversion unit.

In a solid-state imaging device, an annular portion (zone plate) having a concave-convex shape is provided on one side of a photoelectric conversion unit, wherein the annular portion includes a first annular portion including a semiconductor region (a part of a P-type semiconductor region), and a second annular portion including a fixed charge film and an insulating film arranged to surround the first annular portion. The annular portion having a concave-convex shape collects light incident through the on-chip lens, onto the photoelectric conversion unit through a lens effect. Thus, the solid-state imaging device includes the annular portion that has a concave-convex shape and exhibits a lens effect, and thus may reduce the occurrence of color mixing between pixels.

### SUMMARY

One of indicators for evaluating the performance of a solid-state imaging device is the light absorbency in a photoelectric conversion unit. A solid-state imaging device exhibits high quantum efficiency (photoelectric conversion efficiency) as a photoelectric conversion unit has higher light absorbency.

As described above, the solid-state imaging device may reduce color mixing by installing an additional structure, such as an annular portion having a concave-convex shape, in the photoelectric conversion unit. However, the solid-state imaging device of Japanese patent publication No. 2022-108744 does not specifically mention that it seeks to improve the quantum efficiency of the photoelectric conversion unit by focusing research on the structure of the photoelectric conversion unit. Therefore, it may be seen that the solid-state imaging device has room for further improvement in the quantum efficiency of the photoelectric conversion unit.

The inventive concept has been made to solve the above issue, and is to provide a solid-state imaging device that enables reduction of color mixing and improvement of light absorbency in a photoelectric conversion unit.

According to an aspect of the inventive concept, there is provided a solid-state imaging device including a pixel array including a plurality of pixels, wherein each of the plurality of pixels includes a photoelectric conversion unit configured to convert light into an electric charge, an on-chip lens installed on one side of the photoelectric conversion unit, wiring layers installed on another side of the photoelectric conversion unit, and a first periodic structure that is installed on the one side of the photoelectric conversion unit and has periodicity in a horizontal direction that is perpendicular to a stacking direction of the photoelectric conversion unit, the first periodic structure includes a plurality of first layers and a plurality of second layers that have refractive indices lower than refractive indices of the plurality of first layers, and in at least one of the plurality of pixels, the first layers and the second layers of the first periodic structure are arranged such that volume proportions of the first layers in a pixel central portion in the horizontal direction are greater than volume proportions of the second layers in the pixel central portion, and the volume proportions of the first layers decrease from the pixel central portion toward a pixel peripheral portion in the horizontal direction.

In an embodiment, widths of the second layers in the horizontal direction may be different from each other, and the first periodic structure may be configured such that the volume proportions of the first layers decrease from the pixel central portion toward the pixel peripheral portion.

In an embodiment, depths of the second layers in the stacking direction may be different from each other, and the first periodic structure may be configured such that the volume proportions of the first layers decrease from the pixel central portion toward the pixel peripheral portion.

In an embodiment, a period of the first periodic structure may be set to a certain value based on a wavelength and an angle of incidence of light received by the photoelectric conversion unit, and may include a length that is less than the wavelength of the received light, and enables generation of diffracted light in the photoelectric conversion unit.

In an embodiment, depths of the first layers and depths of the second layers in the stacking direction may be equal to a wavelength of light received by the photoelectric conversion unit, and a thickness of the photoelectric conversion unit may be greater than the depths of the first layers and the depths of the second layers.

In an embodiment, the photoelectric conversion unit may be covered at least in part by a dielectric layer having a refractive index lower than the refractive indices of the first layers, and a period of the first periodic structure may include a length that enables diffracted light, which is generated in the photoelectric conversion unit, to be totally reflected at a boundary between the photoelectric conversion unit and the dielectric layer.

In an embodiment, the wiring layer, which is arranged at a position closest to the photoelectric conversion unit in the stacking direction, may have a reflective structure that reflects light transmitted through the photoelectric conversion unit.

In an embodiment, the pixel including the first periodic structure may further include a second periodic structure that is installed on the one side of the photoelectric conversion unit and has periodicity in the horizontal direction, and the second periodic structure may include a plurality of third layers having refractive indices equal to refractive indices of the first layers, and a plurality of fourth layers having refractive indices equal to refractive indices of the second layers.

In an embodiment, the second periodic structure may have periodicity that is identical to the periodicity of the first periodic structure.

In an embodiment, distribution of the volume proportions of the first layers in the first periodic structure may be identical to distribution of volume proportions of the third layers in the second periodic structure, and distribution of the volume proportions of the second layers in the first periodic structure may be identical to distribution of volume proportions of the fourth layers in the second periodic structure.

According to an aspect of the inventive concept, there is provided a solid-state imaging device comprising a pixel array comprising a plurality of pixels, wherein each of the plurality of pixels comprises: a photoelectric conversion unit configured to convert light into an electric charge; an on-chip lens installed on one side of the photoelectric conversion unit; a wiring layer installed on another side of the photoelectric conversion unit; and a first periodic structure that is installed on the one side of the photoelectric conversion unit and has periodicity in a horizontal direction that is perpendicular to a stacking direction of the photoelectric conversion unit, wherein the first periodic structure comprises a plurality of first layers and a plurality of second layers that have refractive indices lower than refractive indices of the plurality of first layers, wherein in at least one of the plurality of pixels, the first layers and the second layers of the first periodic structure are arranged such that volume proportions of the first layers in a pixel central portion are greater than volume proportions of the second layers in the pixel central portion, and the volume proportions of the first layers decrease from the pixel central portion toward a pixel peripheral portion in the horizontal direction, wherein the pixel comprising the first periodic structure further comprises a second periodic structure that is installed on the one side of the photoelectric conversion unit and has periodicity in the horizontal direction, and wherein the second periodic structure comprises a plurality of third layers having refractive indices equal to the refractive indices of the first layers, and a plurality of fourth layers having refractive indices equal to the refractive indices of the second layers.

According to an aspect of the inventive concept, there is provided a solid-state imaging device comprising a pixel array comprising a plurality of pixels, wherein each of the plurality of pixels comprises: a photoelectric conversion unit configured to convert light into an electric charge; an on-chip lens installed on one side of the photoelectric conversion unit; a wiring layer installed on another side of the photoelectric conversion unit; and a first periodic structure that is installed on the one side of the photoelectric conversion unit and has periodicity in a horizontal direction that is perpendicular to a stacking direction of the photoelectric conversion unit, wherein the first periodic structure comprises a plurality of first layers and a plurality of second layers that have refractive indices lower than refractive indices of the plurality of first layers, and wherein in at least one of the plurality of pixels, depths of the second layers of the first periodic structure are equal to each other, and widths of the second layers increase from a pixel central portion toward a pixel peripheral portion.

### BRIEF DESCRIPTION OF THE DRAWINGS

Embodiments will be more clearly understood from the following detailed description taken in conjunction with the accompanying drawings in which:

FIG. 1 is a block diagram illustrating a solid-state imaging device according to an embodiment;

FIG. 2 is a plan view illustrating a first periodic structure of a pixel according to a first embodiment;

FIG. 3 is a cross-sectional view of pixels according to the first embodiment, taken along a stacking direction;

FIG. 4A is a cross-sectional view illustrating a first periodic structure of a pixel that is arranged at a pixel array central portion, according to the first embodiment;

FIG. 4B is a cross-sectional view illustrating a first periodic structure of a pixel that is arranged at a pixel array peripheral portion, according to the first embodiment;

FIG. 5 is a diagram for describing a functional effect of a first periodic structure of a pixel, according to the first embodiment;

FIG. 6 is a diagram for describing a functional effect of a first periodic structure of a pixel, according to the first embodiment;

FIG. 7 is a cross-sectional view for describing a functional effect of a first periodic structure of a pixel, according to the first embodiment;

FIG. 8 is a cross-sectional view illustrating a first periodic structure according to modified example 1;

FIG. 9 is a cross-sectional view illustrating a first periodic structure according to modified example 2;

FIG. 10 is a cross-sectional view illustrating a first periodic structure according to modified example 3;

FIG. 11 is a plan view illustrating a first periodic structure according to modified example

4;

FIG. 12 is a plan view illustrating a first periodic structure according to modified example 5;

FIG. 13 is a plan view illustrating a first periodic structure according to modified example 6;

FIG. 14 is a plan view illustrating a first periodic structure according to modified example 7;

FIG. 15 is a plan view illustrating a first periodic structure according to modified example 8;

FIG. 16 is a cross-sectional view of the pixels according to a second embodiment, taken along a stacking direction;

FIG. 17 is a cross-sectional view for describing a functional effect of a first periodic structure of a pixel, according to the second embodiment;

FIG. 18 is a cross-sectional view of pixels according to a third embodiment, taken along a stacking direction;

FIG. 19 is a diagram for describing a functional effect of a first periodic structure of a pixel, according to the third embodiment;

FIG. 20 is a cross-sectional view of pixels according to a fourth embodiment, taken along a stacking direction;

FIG. 21 is a diagram for describing a functional effect of a first periodic structure of a pixel, according to the fourth embodiment;

FIG. 22 is a cross-sectional view of pixels according to a fifth embodiment, taken along a stacking direction; and

FIG. 23 is a diagram for describing a functional effect of a first periodic structure of a pixel, according to the fifth embodiment.

### DETAILED DESCRIPTION OF THE EMBODIMENTS

In the drawings, the size and relative sizes of layers and regions may be exaggerated for clarity. Like references characters refer to like elements throughout. Though the different figures show variations of exemplary embodiments, these figures are not necessarily intended to be mutually exclusive from each other. Rather, as will be seen from the context of the detailed description below, certain features depicted and described in different figures can be combined with other features from other figures to result in various embodiments, when taking the figures and their description as a whole into consideration.

### First Embodiment

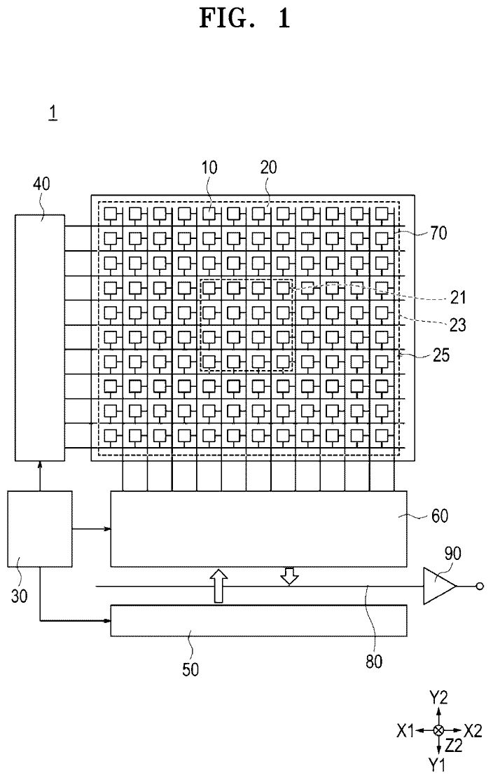

Hereinafter, a first embodiment will be described with reference to FIGS. 1 to 7. In addition, a dimensional ratio in the drawings may be exaggerated for convenience of description, and may differ from the actual ratio.

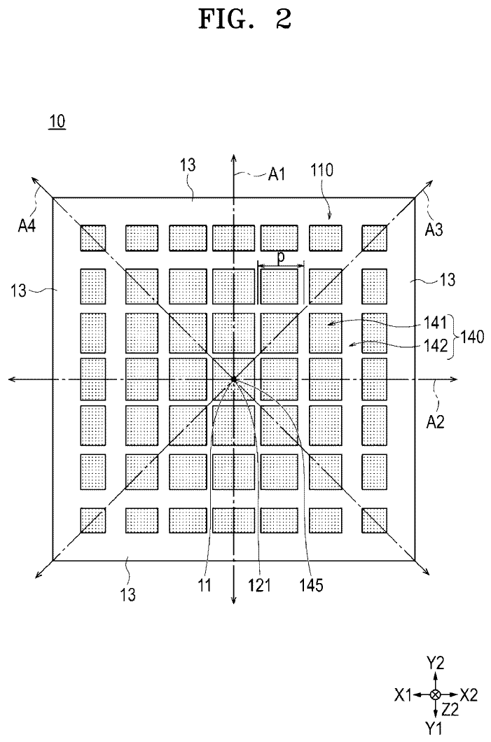

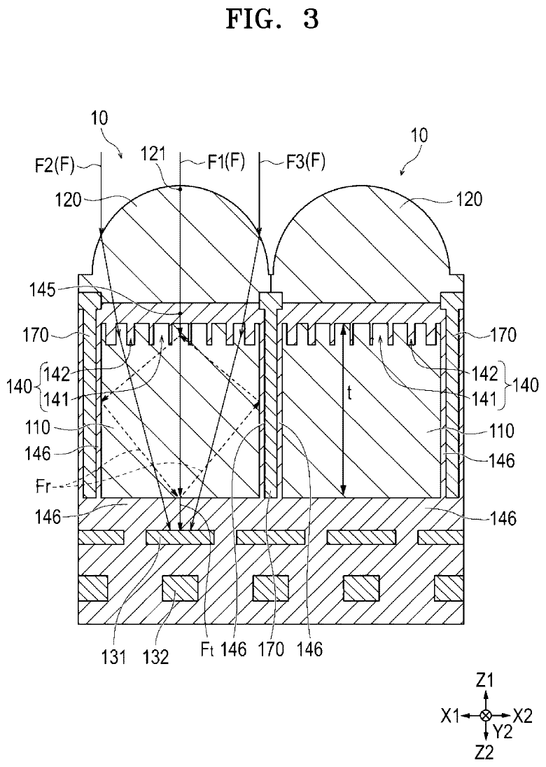

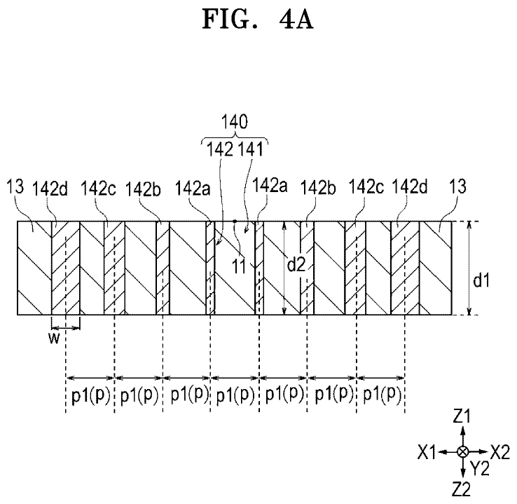

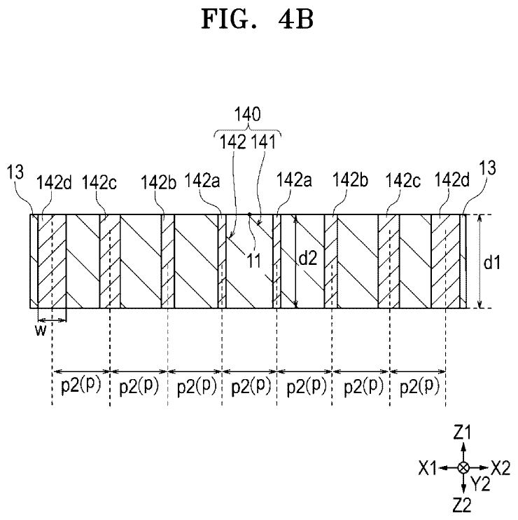

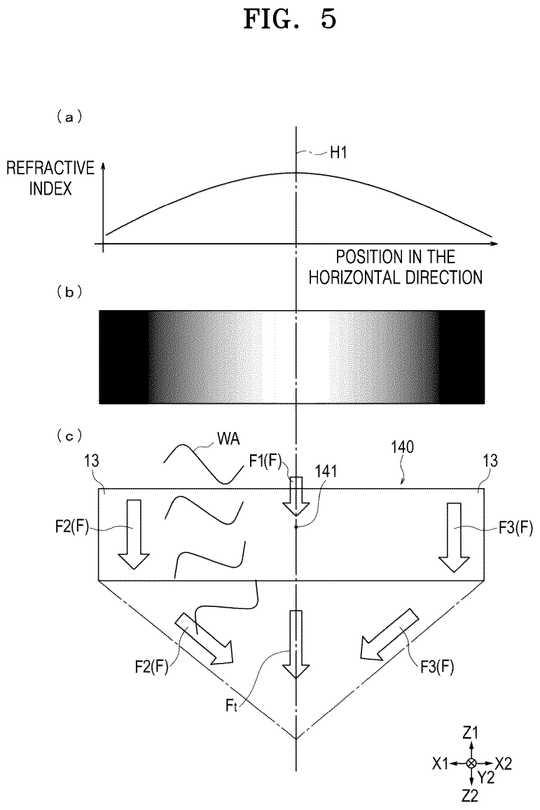

FIG. 1 is a block diagram schematically illustrating an overall configuration of a solid-state imaging device 1 according to the present embodiment. FIG. 2 is a plan view illustrating a single pixel 10 provided in the solid-state imaging device 1. FIG. 3 is a cross-sectional view of the pixels 10 illustrated in FIG. 2, taken along a stacking direction. FIG. 4A is a cross-sectional view schematically illustrating a portion of a first periodic structure 140 arranged in a central portion 21 of a pixel array. FIG. 4B is a cross-sectional view schematically illustrating a portion of the first periodic structure 140 arranged in a peripheral portion 23 of a pixel array. FIGS. 5 to 7 are diagrams for describing functional effects of the first periodic structure 140.

The solid-state imaging device 1 according to the present embodiment is configured as a solid-state imaging device in the form of a complementary metal-oxide-semiconductor (CMOS) device.

As illustrated in FIGS. 1 and 2, the solid-state imaging device 1 includes a pixel array 20 consisting of a plurality of pixels 10 configured to output pixel signals, a control circuit 30 configured to generate an operating signal for operating each unit pixel of the solid-state imaging device 1, a vertical driver circuit 40 configured to vertically scan each pixel 10 and control the output of a pixel signal according to the amount of light received by each pixel 10, a horizontal driver circuit 50 configured to output a horizontal scanning pulse, a column signal processing circuit 60 configured to process a pixel signal output from each pixel 10 to generate an image signal, a vertical signal line 70 configured to transmit a pixel signal generated from each pixel 10 to the column signal processing circuit 60, a horizontal signal line 80 configured to output an image signal from the column signal processing circuit 60, and an output circuit 90 configured to process an image signal received through the horizontal signal line 80 and output the processed signal.

For components of the solid-state imaging device 1 other than the pixels 10, any known configuration in the technical field of solid-state imaging devices may be arbitrarily and selectively employed. Thus, in the present specification, descriptions of components other than the pixels 10 will be appropriately omitted.

As illustrated in FIG. 1, the plurality of pixels 10 are regularly arranged on a substrate 25. The pixel array 20 consists of the plurality of pixels 10 arranged in a two-dimensional array in the plan view of FIG. 1. The substrate 25 on which the pixels 10 are arranged is a semiconductor substrate, such as a silicon (Si) substrate. As used herein, the term “pixel” or “unit pixel” refers to a sensor element of an image sensor, and may refer to a smallest addressable light-sensing element of the image sensor.

As illustrated in FIGS. 2 and 3, the solid-state imaging device 1 includes a photoelectric conversion unit 110 installed in each pixel 10. In addition, FIG. 3 illustrates an example of two pixels 10 adjacent to each other in a horizontal direction.

In the present specification, a direction in which an on-chip lens 120 and the photoelectric conversion unit 110 are stacked (a direction indicated by the arrow Z1 and Z2 in FIG. 3) is referred to as the “stacking direction.” In addition, a direction orthogonal to the stacking direction (a direction parallel to each arrow X1, X2, Y1, and Y2 in FIG. 2) is referred to as a “horizontal direction.”

As illustrated in FIGS. 2 and 3, the pixel 10 includes the photoelectric conversion unit 110 configured to convert light into an electric charge, the on-chip lens 120 installed on one side of the photoelectric conversion unit 110 (the side indicated by the arrow Z1, hereinafter, also simply referred to as ‘Z1 side’), wiring layers 131 and 132 installed on the other side of the photoelectric conversion unit 110 (the side indicated by the arrow Z2, hereinafter also simply referred to as ‘Z2 side’), and a first periodic structure 140 that is installed on the Z1 side of the photoelectric conversion unit 110 and has periodicity in the horizontal direction of the photoelectric conversion unit 110. As discussed further below, the first periodic structure 140 includes a plurality of first layers 141 and a plurality of second layers 142.

The solid-state imaging device 1 is configured as a so-called back-illuminated type. Thus, the on-chip lens 120 is arranged on the back side of the pixel 10 (the same side as the Z1 side). Light F incident on the pixel 10 enters the photoelectric conversion unit 110 from the Z1 side through the on-chip lens 120.

In the drawings, for convenience of description, respective components of the light F incident on the on-chip lens 120 are assigned different symbols F1, F2, and F3 according to their positions of incidence on the photoelectric conversion unit 110. In the present specification, the entire incident light is simply referred to as ‘incident light F’.

The photoelectric conversion unit 110 includes a p-type semiconductor region and an n-type semiconductor region. In the photoelectric conversion unit 110, a photodiode is implemented by a p-n junction between the p-type semiconductor region and the n-type semiconductor region, and the photodiode converts light into an electric charge. The photoelectric conversion unit 110 receives light incident through the on-chip lens 120, generates electric charges in correspondence to the amount of light received, and accumulates the generated electric charges in the n-type semiconductor region.

As illustrated in FIGS. 3, 4A, and 4B, the first periodic structure 140 is installed within a certain range in the stacking direction of the photoelectric conversion unit 110. In the present embodiment, as illustrated in FIGS. 4A and 4B, the first periodic structure 140 corresponds to a range in which second layers 142 extend in the stacking direction of the photoelectric conversion unit 110 (a range between an end of the second layer 142 on the Z1 side and another end of the second layer 142 on the Z2 side), and includes a region (part) in which layers 141 and 142 are alternately arranged in the horizontal direction. In some example embodiments, the first periodic structure 140 may have a thickness (or height) in the stacking direction that is equal to the thickness (or height) of the second layers 142 in the stacking direction.

As illustrated in FIG. 3, the photoelectric conversion units 110, which are adjacent to each other in the horizontal direction, are separated from each other by an insulating film 170. In example embodiments, a lower surface of the insulating film 170 may be at the same level as lower surfaces of the adjacent photoelectric conversion unit 110, and an upper surface of the insulating film 170 may be at a higher level than upper surfaces of the adjacent photoelectric conversion unit 110. As the pixel 10 includes the insulating film 170, when a signal charge exceeding a saturation charge amount occurs, the excess signal charge may be prevented from flowing out from the photoelectric conversion unit 110 to another photoelectric conversion unit 110 adjacent thereto in the horizontal direction. As a constituent material of the insulating film 170, for example, a silicon oxide film, a silicon nitride film, a silicon oxynitride film, a resin film, and the like may be used. In addition, as the insulating film 170, a film without positive fixed charges or a film with a small amount of positive fixed charges may be used.

A fixed charge film may be installed between the photoelectric conversion units 110 that are adjacent to each other in the horizontal direction. As the fixed charge film is installed in the pixel 10, the pixel 10 may reduce noise by reducing the occurrence of dark current. As a constituent material of the fixed charge film, for example, an oxide film or a nitride film including at least one metal element from among hafnium (Hf), aluminum (Al), zirconium (Zr), tantalum (Ta), and titanium (Ti) is used. Methods of forming the fixed charge film include, for example, chemical vapor deposition (CVD), sputtering, atomic layer deposition (ALD), and the like.

The on-chip lens 120 collects the incident light F entering from the Z1 side. The light collected by the on-chip lens 120 enters the photoelectric conversion unit 110.

As illustrated in FIG. 2, a central portion 121 of the on-chip lens 120 in the horizontal direction is arranged to overlap with a pixel central portion 11 of the pixel 10.

As illustrated in FIG. 3, the solid-state imaging device 1 includes a plurality of wiring layers 131 and 132 arranged with intervals therebetween in the stacking direction. Hereinafter, the wiring layer 131 arranged closest to the photoelectric conversion unit 110 is referred to as a ‘first wiring layer’, and the wiring layer 132 arranged further away from the photoelectric conversion unit 110 than the first wiring layer 131 is referred to as a ‘second wiring layer’. In addition, there are no particular limitations on the number of wiring layers installed in one solid-state imaging device 1, their arrangement in the horizontal direction, and their cross-sectional shape in the stacking direction, and they may be arbitrarily modified.

The first wiring layer 131 and the second wiring layer 132 extract, as pixel signals, signal charges generated and accumulated by the photoelectric conversion unit 110. The first wiring layer 131 and the second wiring layer 132 output the extracted pixel signals through the vertical signal line 70.

As illustrated in FIGS. 2 and 3, the first periodic structure 140 includes a plurality of first layers 141, and a plurality of second layers 142 having a lower refractive index than the first layers 141.

A ‘difference in refractive index’ between the first layer 141 and the second layer 142 may be defined, for example, by the physical properties (e.g., dielectric constant) of the constituent materials of the respective layers 141 and 142. In addition, there are no particular limitations on the ‘difference in refractive index’ as long as a lens effect to be described below is exhibited, and diffracted light Fr to be described below is generated inside the photoelectric conversion unit 110.

As constituent materials of the respective layers 141 and 142 for realizing a desired difference in refractive index, for example, a combination of the following materials may be selected.

As a constituent material of the first layer 141, for example, any one of silicon (Si), germanium (Ge), and indium gallium arsenide (InGaAs) may be used. For example, the first layer 141 may be formed of or include any one of silicon (Si), germanium (Ge), and indium gallium arsenide (InGaAs).

In a case in which the first layer 141 is formed of any one of the above materials, for example, any one of silicon dioxide (SiO₂), silicon nitride (SiN), aluminum oxide (AlO), tantalum oxide (TaO), titanium nitride (TiN), and titanium oxide (TiO) may be used as a constituent material of the second layer 142. For example, the second layer 142 may be formed of or include any one of silicon dioxide (SiO₂), silicon nitride (SiN), aluminum oxide (AlO), tantalum oxide (TaO), titanium nitride (TiN), and titanium oxide (TiO).

The first periodic structure 140 is configured to have periodicity in the horizontal direction as described above. The expression ‘having periodicity in the horizontal direction’ means that the arrangement interval of the second layers 142 in the horizontal direction (hereinafter, referred to as ‘period p’) is constant over the entire range in the horizontal direction or an arbitrary partial range in the horizontal direction, as illustrated in FIGS. 2, 4A, and 4B.

As illustrated in FIGS. 4A and 4B, in the pixel 10 of the present embodiment, the period p is constant over the entire range in a direction parallel to the horizontal arrow X1 and X2. However, referring to FIG. 1, the period p of the first periodic structure 140 may also be configured differently in the central portion 21 of the pixel array (an arbitrary region including a center position in a plane direction of the pixel array 20), and in the peripheral portion 23 of the pixel array (an arbitrary region outside the central portion 21 of the pixel array in plan view). For example, a period p1 of the first periodic structure 140 arranged in the central portion 21 (see FIG. 1) of the pixel array illustrated in FIG. 4A may be less than a period p2 of the first periodic structure 140 arranged in the peripheral portion 23 (see FIG. 1) of the pixel array illustrated in FIG. 4B. As the length of the period p varies in the central portion 21 (see FIG. 1) of the pixel array and the peripheral portion 23 (see FIG. 1) of the pixel array, angles at which light incident on the first periodic structure 140 at the central portion 21 (see FIG. 1) of the pixel array and the peripheral portion 23 (see FIG. 1) is diffracted on the surface of the first layer 141 are equivalent to each other, the diffracted light is totally reflected at a boundary between the photoelectric conversion unit 110 and the insulating film 170 that are adjacent to each other in the horizontal direction, and the light is confined within the photoelectric conversion unit 110, enabling the effect of achieving high quantum efficiency in both the central portion 21 (see FIG. 1) of the pixel array and the peripheral portion 23 (see FIG. 1). In addition, in the following description, operation effects according to the present embodiment will be described based on the first periodic structure 140 arranged in the central portion 21 (see FIG. 1) of the pixel array illustrated in FIG. 4A.

FIG. 4A illustrates an example of four second layers 142a, 142b, 142c, and 142d arranged with the period p therebetween, from the pixel central portion 11 of the pixel 10 of FIG. 1 toward a pixel peripheral portion 13 of the pixel 10 in the horizontal direction. For example, FIG. 4A illustrates four second layers 142a, 142b, 142c, and 142d arranged in order in a direction parallel to the horizontal arrow X1 and four second layers 142a, 142b, 142c, and 142d arranged in order in a direction parallel to the horizontal arrow X2. However, there are no particular limitations on the number of second layers 142 provided in the pixel 10.

In the plan view of FIG. 2, the first layers 141 are arranged in a quadrangular pattern with a certain area.

In the plan view of FIG. 2, the second layers 142 are arranged in a line pattern extending to space out the first layers 141 that are adjacent to each other in the horizontal direction.

In the cross-sectional views of FIGS. 3 and 4A, a concave-convex structure formed by the first layers 141 and the second layers 142 is installed on a surface of the photoelectric conversion unit 110 on the Z1 side. The concave-convex structure is formed by the second layers 142 having a rectangular cross-sectional shape and extending from the Z1 side of the photoelectric conversion unit 110 to penetrate into the first layers 141.

FIG. 4A illustrates a direction parallel to the arrows X1 and X2, as a horizontal direction that serves as a reference for the period p of the first periodic structure 140. However, the horizontal direction that serves as a reference for the periodicity of the first periodic structure 140 is not limited to a direction parallel to the arrows X1 and X2. For example, the first periodic structure 140 may be configured to have a period p in at least one of the direction of an arrow A1 passing through the pixel central portion 11 and orthogonal to the arrow X1 and X2 in the plan view of FIG. 2, the direction of an arrow A2 passing through the pixel central portion 11 and orthogonal to the arrow Y1 and Y2, and the directions of arrows A3 and A4 passing through the pixel central portion 11 and intersecting the arrows A1 and A2 at 45° in the plan view.

As illustrated in FIG. 2, the first layer 141 is arranged in a central portion 145 of the first periodic structure 140 in the horizontal direction. The central portion 145 of the first periodic structure 140 in the horizontal direction is arranged to overlap with the pixel central portion 11.

In the solid-state imaging device 1, the first periodic structure 140 in at least one of the plurality of pixels 10 has the following configuration.

As illustrated in FIGS. 2, 3, and 4A, in the first periodic structure 140, the first layers 141 and the second layers 142 are arranged such that, in the pixel central portion 11 in the horizontal direction, the volume proportions of the first layer 141 are greater than the volume proportions of the second layer 142, and the volume proportions of the first layers 141 decrease from the pixel central portion 11 toward the pixel peripheral portion 13 in the horizontal direction. In addition, the first layers 141 and the second layers 142 are arranged such that the volume proportions of the second layers 142 increase from the pixel central portion 11 toward the pixel peripheral portion 13 in the horizontal direction. For example, when viewed in cross-section, the width of the first layer 141 becomes progressively narrower as the distance increases from the pixel central portion 11, and the width of the second layer becomes progressively wider as the distance increases from the pixel central portion 11.

Regarding the term ‘volume proportion’, for example, the volume proportion of the first layer 141 refers to the proportion of the volume of the first layer 141 with respect to the total volume of the photoelectric conversion unit 110, and the volume proportion of the second layer 142 refers to the proportion of the volume of the second layer 142 with respect to the total volume of the photoelectric conversion unit 110.

The functional effects of the first periodic structure 140 (collection of incident light through a lens effect) will be described with reference to FIG. 5.

(a) of FIG. 5 is a graph showing a relationship between the magnitude of an average refractive index for lights F1, F2, and F3 incident on the photoelectric conversion unit 110, and horizontal positions in the photoelectric conversion unit 110 (the first periodic structure 140). (b) of FIG. 5 is a color bar showing a magnitude relationship between the refractive indices for the incident lights F1, F2, and F3 indicated to correspond to the horizontal positions in the graph. (c) of FIG. 5 schematically illustrates a principle in which each of the incident lights F1, F2, and F3 is collected by the first periodic structure 140. A straight line H1 illustrated in (a) to (c) of FIG. 5 indicates a position in the first periodic structure 140 where the refractive index is the greatest (the same position as the position of the pixel central portion 11 and the position of the central portion 145 of the first periodic structure 140 in FIG. 2).

In the first periodic structure 140, the volume proportion of the first layer 141 in the pixel central portion 11 is greater than the volume proportion of the second layer 142. In addition, the refractive index of the first layer 141 is greater than the refractive index of the second layer 142. Thus, as illustrated in (a) of FIG. 5, the refractive index of the first periodic structure 140 in the horizontal direction is the greatest in the pixel central portion 11.

In the first periodic structure 140, the first layers 141 and the second layers 142 are arranged such that the volume proportions of the first layers 141 decrease from the pixel central portion 11 toward the pixel peripheral portion 13. Thus, as illustrated in (a) of FIG. 5, the refractive index of the first periodic structure 140 in the horizontal direction gradually decreases from the pixel central portion 11 toward the pixel peripheral portion 13.

The color bar of (b) of FIG. 5 indicates a magnitude relationship in the refractive index distribution in (a) of FIG. 5. In the color bar, a position with a higher refractive index is represented by a lighter color, and a position with a lower refractive index is represented by a darker color. As illustrated in (b) of FIG. 5, a position corresponding to the vicinity of the pixel central portion 11 where the volume proportion of the first layer 141 is greater than the volume proportion of the second layer 142 has a high refractive index. Thus, in the color bar, the position corresponding to the vicinity of the pixel central portion 11 is represented by a color close to white. A position corresponding to the vicinity of the pixel peripheral portion 13 where the volume proportion of the first layer 141 is less than that of the pixel central portion 11 has a low refractive index. Thus, in the color bar, the position corresponding to the vicinity of the pixel peripheral portion 13 is represented by a color close to black.

As illustrated in (c) of FIG. 5, the incident light F1 (actually, some components of the incident light), which has passed through the vicinity of the pixel central portion 11 (the central portion 145 of the first periodic structure 140) and then entered the photoelectric conversion unit 110, passes through a portion of the first periodic structure 140 where the refractive index is high. Thus, the velocity at which the incident light F1 propagates into the first periodic structure 140 decreases.

As illustrated in (c) of FIG. 5, the incident lights F2 and F3 (actually, some components of incident light), which have passed through the pixel peripheral portion 13 and then entered the photoelectric conversion unit 110, passes through a portion of the first periodic structure 140 where the refractive index is less than that in the pixel central portion 11. Thus, when the incident lights F2 and F3 enter the photoelectric conversion unit 110 from the first periodic structure 140, the velocity at which the incident lights F2 and F3 propagate into the first periodic structure 140 increases.

As described above, the incident light F1 differs from the incident lights F2 and F3 in the velocity of propagation, and thus, the incident lights F2 and F3 propagate while refracting inside the first periodic structure 140, like a wavelength component WA schematically illustrated in (c) of FIG. 5. As such, the first periodic structure 140 exhibits a lens effect that collects incident light passing through the first periodic structure 140, onto the first wiring layer 131 arranged on the Z2 side.

In the pixel 10, the first periodic structure 140 may exhibit a lens effect to efficiently allow incident light that has passed through the photoelectric conversion unit 110 to reach the first wiring layer 131 arranged on the Z2 side of the photoelectric conversion unit 110. Thus, the pixel 10 may prevent incident light, which has passed through the photoelectric conversion unit 110, from passing through spaces between the first wiring layers 131 that are adjacent to each other in the horizontal direction (areas where no first wiring layers 131 are arranged in the cross-sectional view of FIG. 3), thereby suppressing the occurrence of color mixing.

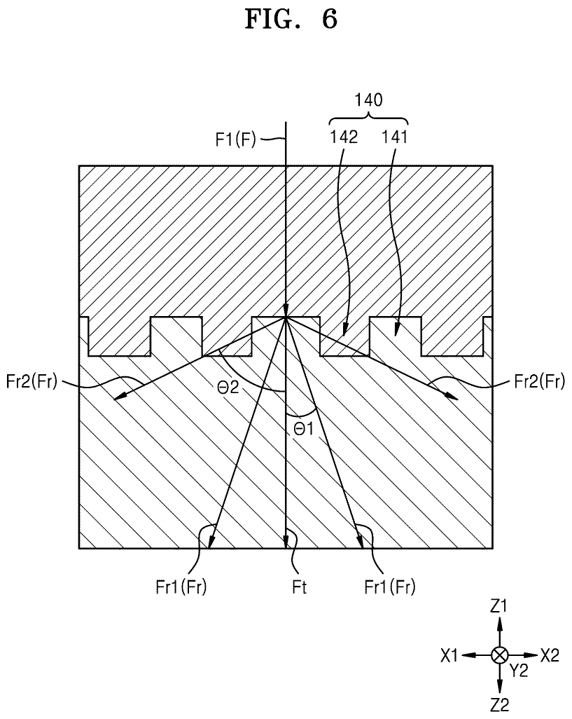

The functional effects of the first periodic structure 140 (improvement of quantum efficiency by diffracted light) will be described with reference to FIG. 6. FIG. 6 is a schematic diagram for describing a principle of generation of diffracted light. Thus, the arrangement or cross-sectional shape of the first layers 141 and the second layers 142 illustrated in FIG. 6 do not have a strict correspondence with the embodiment illustrated in FIG. 3.

The first layers 141 and the second layers 142 are regularly arranged such that the first periodic structure 140 has a period p in the horizontal direction. As illustrated in FIG. 6, the incident light F enters the first periodic structure 140 from the Z1 side of the photoelectric conversion unit 110. The first periodic structure 140 generates diffracted light Fr. The first periodic structure 140 has a constant period p in the horizontal direction. Thus, the first periodic structure 140 may generate the diffracted light Fr in each section in the horizontal direction according to the period p.

As illustrated in FIGS. 3 and 6, the diffracted light Fr generated by the first periodic structure 140 does not propagate in the shortest straight distance from the Z1 side to the Z2 side of the photoelectric conversion unit 110, but propagates in an oblique direction inside the photoelectric conversion unit 110. Thus, the pixel 10 may increase the optical path length of light to be converted into an electric charge by the photoelectric conversion unit 110, compared to a case in which the diffracted light Fr does not occur. In the pixel 10, the amount of light absorbed in the photoelectric conversion unit 110 increases as the optical path length of light to be converted into an electric charge by the photoelectric conversion unit 110 increases. Due to this, the pixel 10 may exhibit high quantum efficiency in the photoelectric conversion unit 110.

The period p of the first periodic structure 140 has a certain size based on the wavelength (the same meaning as the wavelength of incident light) and angle of incidence of light received by the photoelectric conversion unit 110. In addition, the period p of the first periodic structure 140 may have a length that is shorter than the wavelength of light received, and appropriate for generating the diffracted light Fr in the photoelectric conversion unit 110.

FIG. 6 illustrates an example of first-order diffracted light Fr1 and second-order diffracted light Fr2 both generated from light received by the first periodic structure 140. As the period p is set to an appropriate length according to the angle of incidence and wavelength of the incident light F, the pixel 10 may generate the first-order diffracted light Fr1 and the second-order diffracted light Fr2 inside the first periodic structure 140.

In the solid-state imaging device 1, for example, in a case in which the angle of incidence of the incident light F is 0° and the wavelength of the incident light F is 940 nm, the length of the period p (in the cross-sectional view of FIG. 4A, the straight distance between the centers of the second layers 142 adjacent to each other in the horizontal direction) is preferably 400 nm to 600 nm, and more preferably 600 nm. With the period p set in this manner, a diffraction angle θ1 between the incident light F1 and the first-order diffracted light Fr1 is, for example, 25.7°, and a diffraction angle θ2 between the incident light F1 and the second-order diffracted light Fr2 is, for example, 60.5°.

The length of the period p is not particularly limited as long as the photoelectric conversion unit 110 may generate the diffracted light Fr, considering the angle of incidence and wavelength of the incident light F. For example, even in a case in which the angle of incidence of the incident light F is not 0° or the wavelength of the incident light F is not 940 nm, the length of the period p may be changed to an appropriate length based on a known equation for diffraction of light (an equation for transmitted diffracted light). For example, in a case in which the angle of incidence of the incident light F is 30° and the wavelength is 940 nm, the length of the period p may be set within the range of 500 nm to 700 nm.

As illustrated in FIG. 4A, the first periodic structure 140 may be configured such that the volume proportions of the first layers 141 decrease from the pixel central portion 11 toward the pixel peripheral portion 13, because widths w of the second layers 142 in the horizontal direction are different from each other.

In the first periodic structure 140 illustrated in FIG. 4A, the second layers 142a, 142b, 142c, and 142d have the same depth d2. In addition, in the first periodic structure 140, the width w gradually increases from the second layers 142a arranged near the pixel central portion 11, toward the second layers 142d arranged in the pixel peripheral portion 13. In the pixel 10, the widths w of the respective second layers 142a, 142b, 142c, and 142d are different from each other as described above, and thus, the volume proportions of the first layers 141 may gradually decrease from the pixel central portion 11 toward the pixel peripheral portion 13.

A depth d1 of the first layers 141 and the depth d2 of the second layers 142 in the stacking direction may be set to be equivalent to the wavelength of light received by the photoelectric conversion unit 110. In addition, a thickness t of the photoelectric conversion unit 110 (the thickness in the stacking direction illustrated in FIG. 3) may be set to be greater than the depth d1 of the first layers 141 and the depth d2 of the second layers 142.

In a case in which the wavelength of the incident light F is 940 nm as described above, the depth d1 of the first layers 141 and the depth d2 of the second layers 142 may be 940 nm, which is approximately the same as the wavelength of the incident light F. In addition, in a case in which the depth d1 of the first layers 141 and the depth d2 of the second layers 142 are 940 nm, the thickness t of the photoelectric conversion unit 110 may be, for example, 7000 nm.

In addition, the depth d1 of the first layers 141 and the depth d2 of the second layers 142 are not limited to 940 nm. For example, in a case in which the angle of incidence of the incident light F is 0° or 30° and the wavelength is 940 nm, the depth d1 of the first layers 141 and the depth d2 of the second layers 142 may be set to any value within the range of 100 nm to 940 nm.

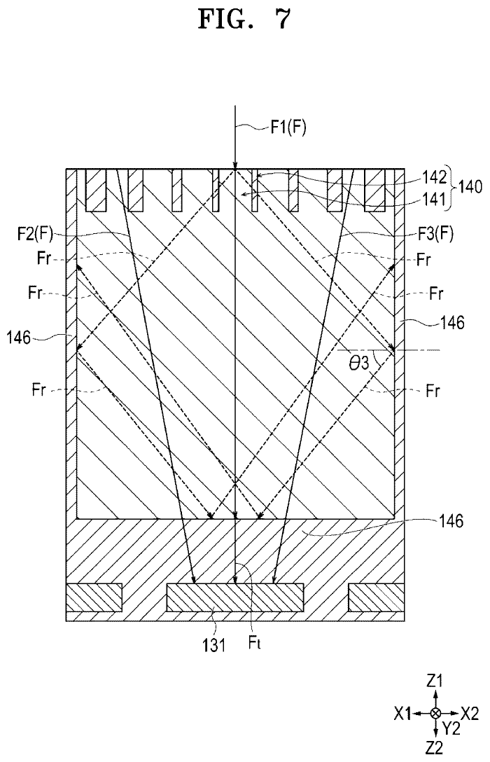

As illustrated in FIGS. 3 and 7, the photoelectric conversion unit 110 is covered at least in part by a dielectric layer 146 having a lower refractive index than that of the first layers 141. FIG. 7 is an enlarged view of a portion of the cross-sectional view of FIG. 3.

The dielectric layer 146 may be arranged to cover the photoelectric conversion unit 110 at three positions, for example, at left and right positions in the stacking direction (X1-side and X2-side positions), and at a Z2-side position. In some example embodiments, the dielectric layer 146 may contact external side and bottom surfaces of the first layers 141. However, the position at which the dielectric layer 146 is arranged is not particularly limited, as long as an effect of totally reflecting diffracted light, which will be described below, may be exhibited.

For example, in a case in which the first layers 141 are formed of any one of the constituent materials described above, a constituent material of the dielectric layer 146 may be the same material as any one of the above-described examples of constituent materials of the second layers 142. For example, the dielectric layer 146 may be formed of or include any one of silicon dioxide (SiO₂), silicon nitride (SiN), aluminum oxide (AlO), tantalum oxide (TaO), titanium nitride (TiN), and titanium oxide (TiO). However, the constituent material of the dielectric layer 146 is not particularly limited, as long as the dielectric layer 146 has a lower refractive index than that of the first layers 141.

The period p of the first periodic structure 140 may be set to a length that allows the diffracted light Fr generated in the photoelectric conversion unit 110 to be totally reflected between the photoelectric conversion unit 110 and the dielectric layer 146. FIG. 7 illustrates a state in which the diffracted light Fr is totally reflected by the dielectric layer 146.

The pixel 10 may increase the optical path length of the diffracted light Fr generated inside the photoelectric conversion unit 110, by totally reflecting the diffracted light Fr in the dielectric layer 146. Thus, the pixel 10 may further increase the amount of light absorbed in the photoelectric conversion unit 110.

As described above, in a case in which the incident light F has an angle of incidence of 0° and a wavelength of 940 nm, the first periodic structure 140 has a period p of 600 nm such that first-order diffracted light Fr1 having a diffraction angle θ1 and second-order diffracted light Fr2 having a diffraction angle θ2 may be generated in the photoelectric conversion unit 110 (see FIG. 6). In a case in which the period p has a length of 600 nm, a condition for the dielectric layer 146 to totally reflect each of the diffracted light Fr1 and the diffracted light Fr2 is that an angle of incidence θ3 (the angle of incidence θ3 for the dielectric layer 146)≥23.7° as illustrated in FIG. 7. This condition may be calculated by substituting the refractive index of the first layer 141 and the refractive index of the dielectric layer 146 into the known Snell's law.

The first periodic structure 140 may be configured such that the volume proportions of the first layers 141 and the second layers 142 are different from each other, based on the wavelength and angle of incidence of light received by the photoelectric conversion unit 110. That is, the specific volume proportion of each layer 141 and 142 in each section in the horizontal direction may be arbitrarily set depending on the wavelength and angle of incidence of the incident light F. In a case in which the angle of incidence of the incident light F is 0° and the wavelength of the incident light F is 940 nm, the volume proportions of the first layers 141 near the pixel central portion 11 (the volume proportions of the first layers 141 with respect to the total volume of the photoelectric conversion unit 110) may be, for example, 60% to 80%, and the volume proportions of the second layers 142 near the pixel central portion 11 (the volume proportions of the second layers 142 with respect to the total volume of the photoelectric conversion unit 110) may be, for example, 20% to 40%. In a case in which the volume proportion of each layer 141 and 142 near the pixel central portion 11 is set as described above, the volume proportions of the first layers 141 near the pixel peripheral portion 13 may be, for example, 20% to 40%, and the volume proportions of the second layers 142 near the pixel peripheral portion 13 may be, for example, 60% to 80%. In addition, that the volume proportions of the first layers 141 and the second layers 142 may be set differently based on the wavelength and angle of incidence of the incident light F received by the photoelectric conversion unit 110 is also applicable to the volume proportions of third layers 153 and fourth layers 154 to be described below in a second embodiment.

A first wiring layer 131 arranged closest to the photoelectric conversion unit 110 in the stacking direction has a reflective structure that reflects light transmitted through the photoelectric conversion unit 110.

In the pixel 10, the first wiring layer 131 has the reflective structure, and thus, at least part of transmitted light Ft, which has passed through the photoelectric conversion unit 110 and reached the first wiring layer 131, may be reflected toward the photoelectric conversion unit 110. In the pixel 10, light reflected from the reflective structure of the first wiring layer 131 enters the photoelectric conversion unit 110, and thus, the optical path length of light inside the photoelectric conversion unit 110 may be further increased. Accordingly, the pixel 10 may further increase the amount of light absorbed in the photoelectric conversion unit 110.

The reflective structure installed in the first wiring layer 131 may be configured by, for example, a metal layer installed on at least part of the surface of the first wiring layer 131 arranged on the side of the photoelectric conversion unit 110. The metal layer may be formed of, for example, tungsten, aluminum, copper, etc.

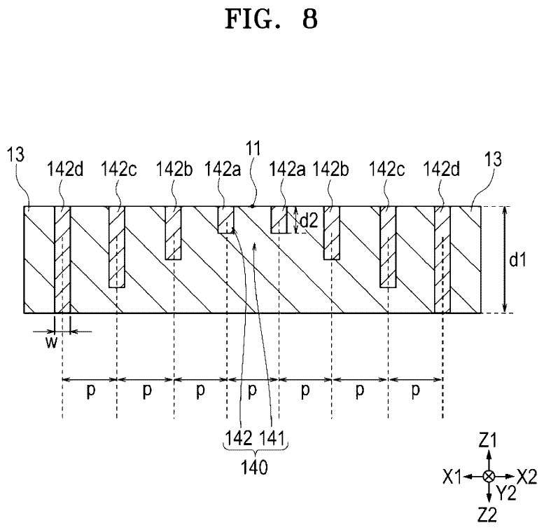

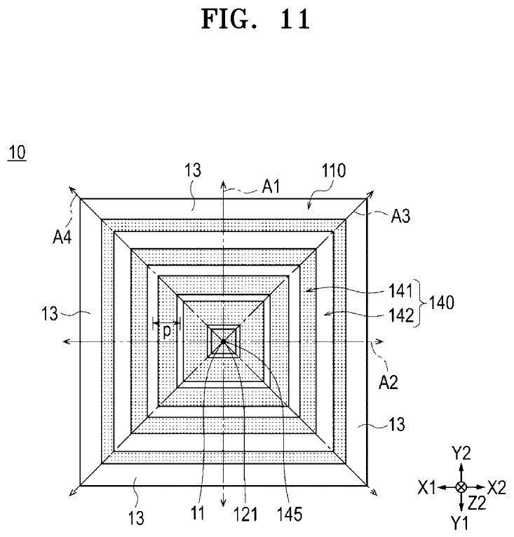

Hereinafter, modified examples regarding the horizontal arrangement of each layer 141 and 142, or the cross-sectional shape of each layer 141 and 142 in the stacking direction will be described with reference to FIGS. 8 to 15. FIGS. 8 to 10 are cross-sectional views of respective modified examples corresponding to the cross-sectional view of FIG. 4, and FIGS. 11 to 15 are plan views of respective modified examples corresponding to the plan view of FIG. 2.

As will be described about each of the following modified examples, the cross-sectional shape of each layer 141 and 142 of the first periodic structure 140 in the stacking direction and the arrangement of each layer 141 and 142 in plan view may be arbitrarily changed as long as the lens effect and the effect of generating diffracted light described above may be achieved.

As illustrated in FIG. 8, the first periodic structure 140 of modified example 1 is configured such that the volume proportions of the first layers 141 decrease from the pixel central portion 11 toward the pixel peripheral portion 13, because the depths d2 of the second layers 142 in the stacking direction are different from each other.

In the first periodic structure 140 illustrated in FIG. 8, the widths w of the respective second layers 142a, 142b, 142c, and 142d) are equal to each other. In addition, in the first periodic structure 140, the depths d2 gradually increase from the second layers 142a arranged near the pixel central portion 11, to the second layers 142d arranged near the pixel peripheral portion 13. In the pixel 10, the depths d2 of the respective second layers 142a, 142b, 142c, and 142d are different from each other, and thus, the volume proportions of the first layers 141 may gradually decrease from the pixel central portion 11 toward the pixel peripheral portion 13.

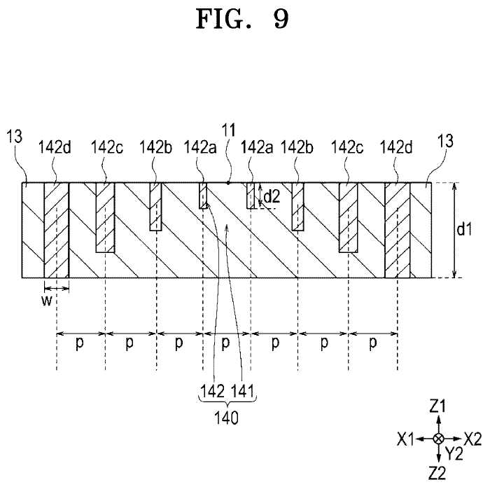

As illustrated in FIG. 9, the first periodic structure 140 of modified example 2 is configured such that the volume proportions of the first layers 141 decrease from the pixel central portion 11 toward the pixel peripheral portion 13, because the second layers 142 differ from each other in the width w in the horizontal direction and in the depth d2 in the stacking direction.

In the first periodic structure 140 illustrated in FIG. 9, the widths w and the depths d2 gradually increase from the second layers 142a arranged near the pixel central portion 11, to the second layers 142d arranged near the pixel peripheral portion 13. In the pixel 10, the second layers 142a, 142b, 142c, and 142d differ from each other in the width w and the depth d2, and thus, the volume proportions of the first layers 141 may gradually decrease from the pixel central portion 11 toward the pixel peripheral portion 13.

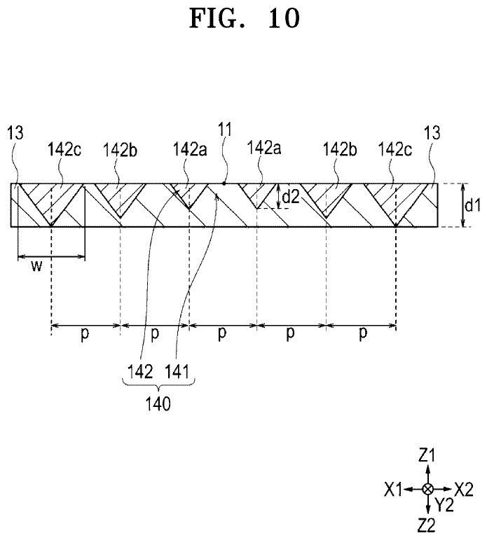

As illustrated in FIG. 10, in the first periodic structure 140 of modified example 3, the second layer 142 has a triangular cross-sectional shape with a base arranged on the Z1 side and a vertex arranged on the Z2 side.

As illustrated in the present modified example, the second layer 142 may be configured to have any cross-sectional shape as long as the magnitude relationship between the volume proportions of the respective layers 141 and 142 in the horizontal direction may be adjusted.

In the first periodic structure 140 of modified example 3, the volume proportions of the first layers 141 decrease from the pixel central portion 11 toward the pixel peripheral portion 13, because the second layers 142 differ from each other in the width w in the horizontal direction and the depth d2 in the stacking direction. In addition, in a case in which the cross-sectional shape of the second layer 142 is the shape of a triangle as illustrated in modified example 3, the width w may be defined as the length of the base of the triangle.

As illustrated in FIG. 11, in the pixel 10 of modified example 4, the first layers 141 and the second layers 142 are arranged in the shape of a square frame in plan view. For example, each of the first layers 141 and the second layers 142 may extend continuously to concentrically surround the pixel central portion 11. Each of the first layers 141 may become narrower as the distance increases from the pixel central portion 11, and each of the second layer 142 may become wider as the distance increases from the pixel central portion 11. When viewed in cross-section, in the pixel 10 of modified example 4, the first layers 141 and the second layers 142 may include features of any one of modified examples 1 to 3 of FIGS. 8 to 10, respectively.

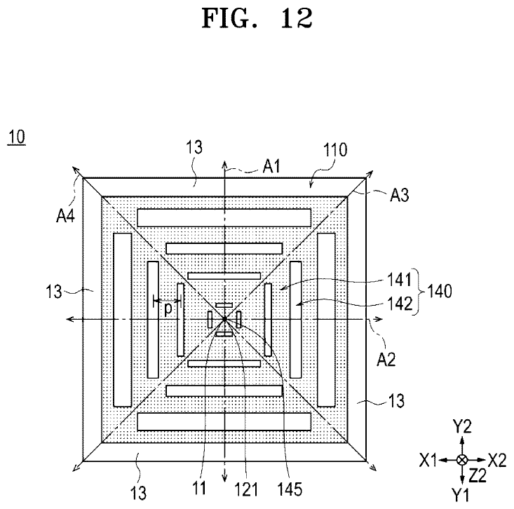

As illustrated in FIG. 12, in the pixel 10 of modified example 5, the second layers 142 are arranged in the shapes of rectangles with certain lengths and widths in plan view. In addition, in the first periodic structure 140 of modified example 5, the first layers 141 are arranged at portions corresponding to vertices of a square formed by the second layers 142 in plan view. When viewed in cross-section, in the pixel 10 of modified example 5, the first layers 141 and the second layers 142 may include features of any one of modified examples 1 to 3 of FIGS. 8 to 10, respectively.

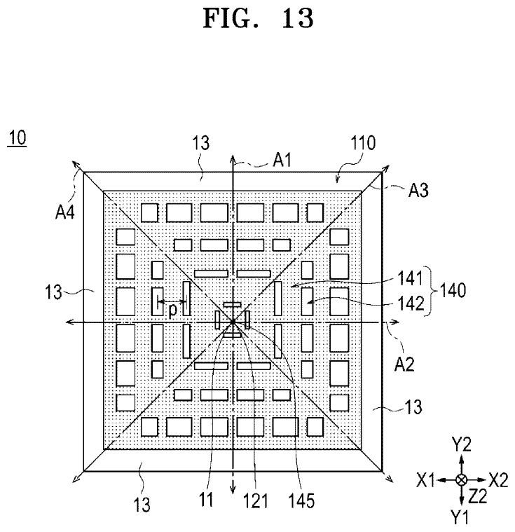

As illustrated in FIG. 13, in the pixel 10 of modified example 6, the second layers 142 are arranged in the shapes of rectangles with certain lengths and widths in plan view. The lengths of the second layers 142 in each direction of arrows A1 and A2 are less than the lengths of the second layers 142 of modified example 5. That is, the second layers 142 of modified example 6 has a structure in which the second layers 142 of modified example 5 are subdivided in plan view. When viewed in cross-section, in the pixel 10 of modified example 6, the first layers 141 and the second layers 142 may include features of any one of modified examples 1 to 3 of FIGS. 8 to 10, respectively.

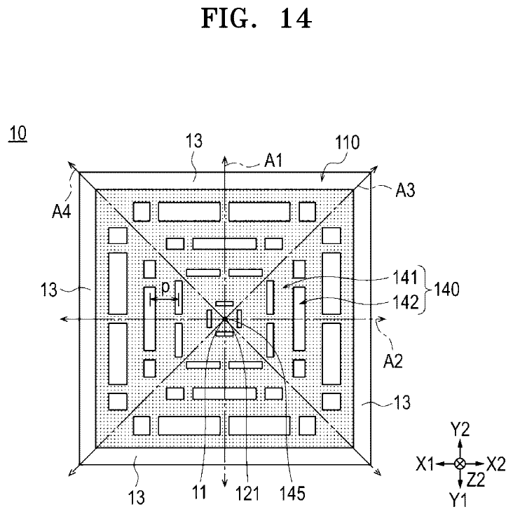

As illustrated in FIG. 14, in the pixel 10 of modified example 7, the second layers 142 are arranged in the shapes of rectangles with certain lengths and widths in plan view. The second layers 142 of modified example 7 are formed such that some of the second layers 142 of modified example 6 are connected to each other in plan view. When viewed in cross-section, in the pixel 10 of modified example 7, the first layers 141 and the second layers 142 may include features of any one of modified examples 1 to 3 of FIGS. 8 to 10, respectively.

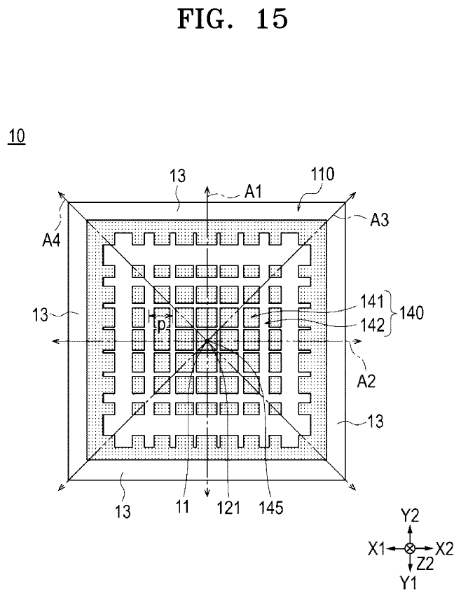

As illustrated in FIG. 15, in the pixel 10 of modified example 8, the second layers 142 are arranged to be connected to each other in the longitudinal and transverse directions in plan view, like the squares of a checkerboard. When viewed in cross-section, in the pixel 10 of modified example 8, the first layers 141 and the second layers 142 may include features of any one of modified examples 1 to 3 of FIGS. 8 to 10, respectively.

In addition, the first periodic structure 140 may be arbitrarily changed as long as it has a certain period p across the entire area or a partial area in the horizontal direction, in addition to the arrangement of each layer 141 and 142 described above regarding modified examples 4 to 8. For example, each layer 141 and 142 may be arranged in a concentric pattern with the center arranged in the pixel central portion 11 in plan view.

As described above, the solid-state imaging device 1 according to the first embodiment is a solid-state imaging device including the pixel array 20 consisting of a plurality of pixels 10, wherein the pixel 10 includes the photoelectric conversion unit 110 configured to convert light into an electric charge, the on-chip lens 120 installed on the Z1 side of the photoelectric conversion unit 110, the first wiring layer 131 installed on the Z2 side of the photoelectric conversion unit 110, and the first periodic structure 140 that is installed on the Z1 side of the photoelectric conversion unit 110 and has periodicity in a horizontal direction that is perpendicular to a stacking direction of the photoelectric conversion unit 110, and the first periodic structure 140 includes a plurality of first layers 141 and a plurality of second layers 142 having a lower refractive index than that of the first layers 141. In at least one of the plurality of pixels 10, the first periodic structure 140 may be configured such that the volume proportions of the first layers 141 in the pixel central portion 11 in the horizontal direction are greater than the volume proportions of the second layers 142 in the pixel central portion 11, and the first layers 141 and the second layers 142 may be arranged such that the volume proportions of the first layers 141 decrease from the pixel central portion 11 toward the pixel peripheral portion 13 in the horizontal direction.

In the pixel 10 of the solid-state imaging device 1 of the present embodiment, the first periodic structure 140 installed on the Z1 side of the photoelectric conversion unit 110 may exhibit a lens effect that collects the incident light F entering through the on-chip lens 120, onto the photoelectric conversion unit 110, and may generate a larger amount of diffracted light Fr inside the photoelectric conversion unit 110. Thus, the solid-state imaging device 1 may reduce color mixing and improve light absorption in the photoelectric conversion unit 110.

Hereinafter, solid-state imaging devices according to second to fifth embodiments will be described. In the description of the second to fifth embodiments, descriptions of members, configurations, or the like provided above in the first embodiment will not be repeated. In addition, those not specifically described in the second to fifth embodiments may be the same as those in the first embodiment.

### Second Embodiment

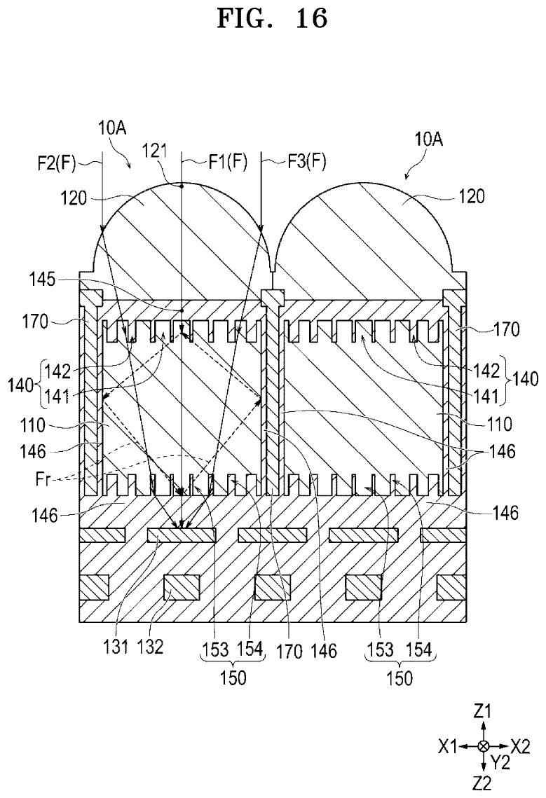

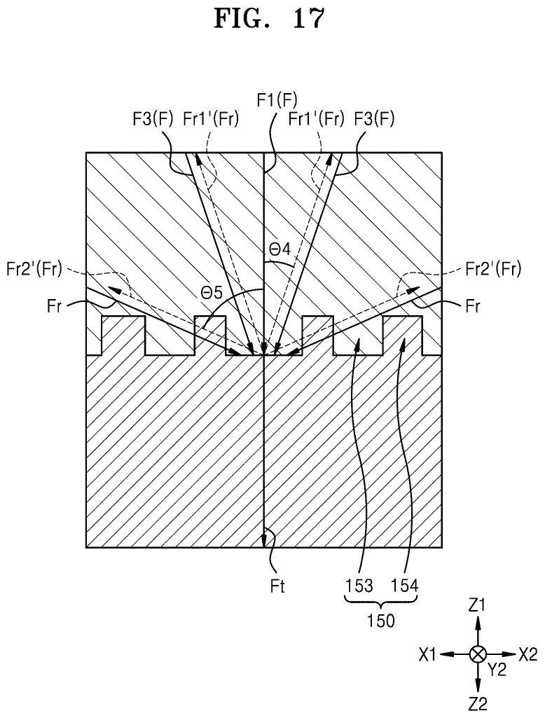

FIG. 16 is a cross-sectional view of pixels 10A according to a second example embodiment, taken along a stacking direction. FIG. 17 is a cross-sectional view for describing functional effects of the pixel 10A.

As illustrated in FIG. 16, the pixel 10A according to the second embodiment includes the first periodic structure 140 and a second periodic structure 150 that is installed on the Z2 side of the photoelectric conversion unit 110 and has periodicity in a horizontal direction perpendicular to the stacking direction.

The second periodic structure 150 includes the third layers 153 having the same refractive index as that of the first layers 141, and the fourth layers 154 having the same refractive index as that of the second layers 142.

The third layer 153 may be formed of, for example, the same material as the material exemplified above as the constituent material of the first layer 141. The fourth layer 154 may be formed of, for example, the same material as the material exemplified above as the constituent material of the second layer 142. In a case in which the third layers 153 and the fourth layers 154 are configured as described above, the first layers 141 and the third layer 153 have the same optical properties (e.g., the refractive index), and the second layers 142 and the fourth layers 154 also have the same optical properties (e.g., the refractive index). Thus, the difference in the refractive index between the third layers 153 and the fourth layers 154 is the same as the difference in the refractive index between the first layers 141 and the second layers 142.

The functional effects (improvement of quantum efficiency by reflection of diffracted light) of the second periodic structure 150 will be described with reference to FIG. 17. In addition, FIG. 17 is a schematic diagram for describing a principle of reflection of diffracted light, and the arrangement or cross-sectional shapes of the third layers 153 and the fourth layers 154 illustrated in FIG. 17 do not have a strict correspondence with the embodiment illustrated in FIG. 16.

In the pixel 10A, when light that has passed through the photoelectric conversion unit 110 reaches the second periodic structure 150 arranged on the Z2 side of the photoelectric conversion unit 110, diffracted light Fr is generated at a boundary between the photoelectric conversion unit 110 and the second periodic structure 150. In addition, FIG. 17 illustrates an example of first-order diffracted lights Fr1′ generated from incident lights F2 and F3 collected by the on-chip lens 120, and second-order diffracted lights Fr2′ generated from diffracted lights Fr1 and Fr2 reflected from the dielectric layer 146 (see FIG. 7).

In the pixel 10A, as the diffracted light Fr is generated in the second periodic structure 150, light that has reached the second periodic structure 150 is moved from the Z2 side of the photoelectric conversion unit 110 toward the Z1 side. Thus, the pixel 10A may further increase the optical path length of light to be converted into an electric charge by the photoelectric conversion unit 110. Therefore, the pixel 10A may further increase the amount of light absorbed in the photoelectric conversion unit 110.

As illustrated in FIG. 16, the second periodic structure 150 may be configured to have the same periodicity as that of the first periodic structure 140. That is, the length of the period p of the first periodic structure 140 and the length of the period p of the second periodic structure 150 may be set to be approximately equal to each other. As described above, the length of the period p of the first periodic structure 140 may be set to 600 nm, based on the angle of incidence (e.g., 0°) and wavelength (e.g., 940 nm) of the incident light F. Thus, in the present embodiment, the length of the period p of the second periodic structure 150 is set to 600 nm.

In the pixel 10A, the length of the period p of the first periodic structure 140 and the length of the period p of the second periodic structure 150 are set to be approximately equal to each other, and thus, diffraction angles for diffracted lights Fr generated on the Z1 side and the Z2 side of the photoelectric conversion unit 110, respectively, may be approximately equal to each other. In the pixel 10A, the diffraction angle of the diffracted lights Fr generated on the Z1 side and the Z2 side of the photoelectric conversion unit 110 are fixed to be approximately equal to each other, making it easy to design an optical path for total reflection of light inside the photoelectric conversion unit 110. In addition, in the pixel 10A, the length of the period p of the second periodic structure 150 arranged on the Z2 side of the photoelectric conversion unit 110 is set to 600 nm, which is equal to the length of the period p of the first periodic structure 140, and thus, light that has reached the second periodic structure 150 may be totally reflected.

In the example illustrated in FIG. 17, a diffraction angle θ4 of the first-order diffracted light Fr1′ generated in the second periodic structure 150 is approximately 60°, which is equal to the diffraction angle θ1 of the first-order diffracted light Fr1 generated in the first periodic structure 140 (see FIG. 6). In addition, a diffraction angle θ5 of the second-order diffracted light Fr2′ generated in the second periodic structure 150 is approximately 26°, which is equal to the diffraction angle θ2 of the second-order diffracted light Fr2 generated in the first periodic structure 140 (see FIG. 6).

In the pixel 10A, the distribution of the volume proportions of the first layers 141 in the first periodic structure 140 is the same as the distribution of the volume proportions of the third layers 153 in the second periodic structure 150. In addition, the distribution of the volume proportions of the second layers 142 in the first periodic structure 140 is the same as the distribution of the volume proportions of the fourth layers 154 in the second periodic structure 150.

In the pixel 10A, as described above, because the distribution of the volume proportions of the first layers 141 is the same as the distribution of the volume proportions of the third layers 153, and the distribution of the volume proportions of the second layers 142 is the same as the distribution of the volume proportions of the fourth layers 154, the diffraction angles of the diffracted lights Fr generated on the Z1 side and the Z2 side of the photoelectric conversion unit 110 are further fixed. Thus, in the pixel 10A, the design of an optical path for totally reflecting light inside the photoelectric conversion unit 110 is further facilitated.

FIG. 16 shows the volume proportion of the first periodic structure 140 in the horizontal direction, and the cross-sectional shape of each layer 141 and 142, as an example of the configuration illustrated in FIGS. 4A and 4B. In addition, in FIG. 16, the second periodic structure 150 is configured to have the same volume proportion and cross-sectional shape as those of the first periodic structure 140. However, when the pixel 10A is configured to have the first periodic structure 140 and the second periodic structure 150, there are no particular limitations on the horizontal volume proportion or cross-sectional shape of each of the first and second periodic structures 140 and 150. For example, each of the first and second periodic structures 140 and 150 may adopt any one of the configurations described above in modified examples 1 to 8.

### Third Embodiment

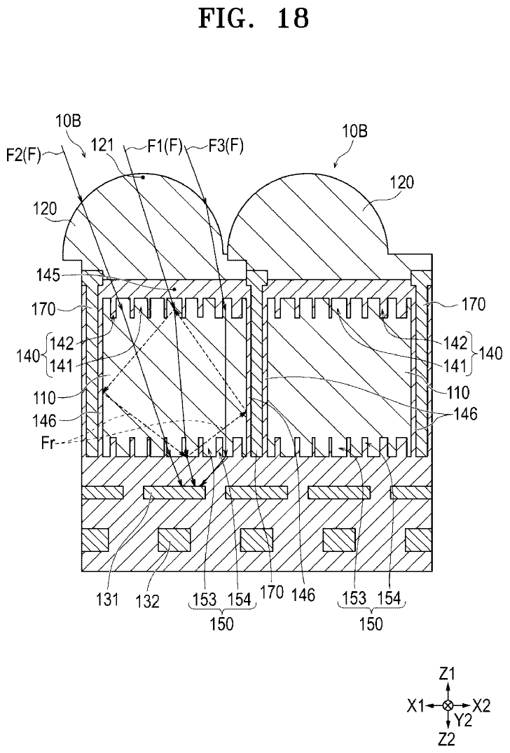

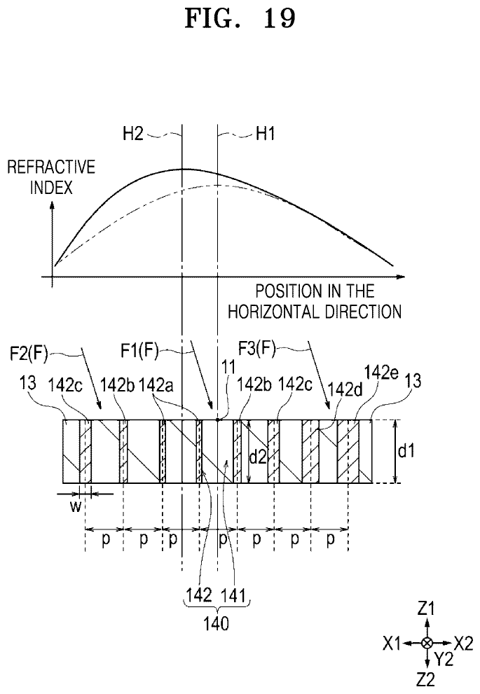

FIG. 18 is a cross-sectional view of pixels 10B according to a third example embodiment, taken along a stacking direction. FIG. 19 includes a graph showing the relationship between the magnitude of an average refractive index for light F incident on the photoelectric conversion unit 110, and horizontal positions in the photoelectric conversion unit 110, and a schematic cross-sectional view of the first periodic structure 140 taken along a stacking direction.

As illustrated in FIGS. 18 and 19, in the pixel 10B according to the third embodiment, a position at which the first layer 141 of the first periodic structure 140 has the largest volume proportion, is arranged at a position corresponding to the position of the central portion 121 (a central portion in the horizontal direction) of the on-chip lens 120.

The central portion 121 of the on-chip lens 120 may be arranged at a certain position between the pixel central portion 11 and the pixel peripheral portion 13, in correspondence with the angle of incidence of light received by the photoelectric conversion unit 110.

The examples illustrated in FIGS. 18 and 19 show a state in which light is incident at a certain angle of incidence from the left side in the drawings (the left side in the horizontal direction).

The central portion 121 of the on-chip lens 120 is arranged at a position displaced toward the side from which the light is coming. When light is incident on the on-chip lens 120 at a certain angle of incidence, in order to efficiently collect the incident light F3 onto the first wiring layer 131 arranged on the Z2 side of the photoelectric conversion unit 110, it is preferable that the incident light F3, which is coming from a more rightward position in the horizontal direction with respect to the central portion 121 than the incident light F1, be further refracted toward the center by the first periodic structure 140. Thus, in the pixel 10B, the position of the central portion 121 of the on-chip lens 120 is set to a position shifted to the left in the horizontal direction, and the position where the volume proportion of the first layer 141 of the first periodic structure 140 is the largest (the positions indicated by imaginary lines H1 in FIG. 19) is arranged to correspond to the position of the central portion 121 of the on-chip lens 120.

In addition, the two-dot chain line in the graph of FIG. 19 represents the distribution of refractive indices in the horizontal direction in a case in which the angle of incidence of the incident light F is 0° (the distribution of refractive indices of the first embodiment shown in FIG. 5). The imaginary line H1 in the graph of FIG. 19 indicates a position in the first periodic structure 140 where the refractive index is the largest (the same position as the pixel central portion 11), as described above in the first embodiment.

In the pixel 10B of the third embodiment, a position at which the volume proportion of the first layer 141 of the first periodic structure 140 is the largest, is arranged to correspond to the position of the central portion 121 of the on-chip lens 120. Thus, even when light F is incident on the first periodic structure 140 at a certain angle of incidence, the light may be efficiently collected onto the first wiring layer 131 arranged on the Z2 side of the photoelectric conversion unit 110.

### Fourth Embodiment

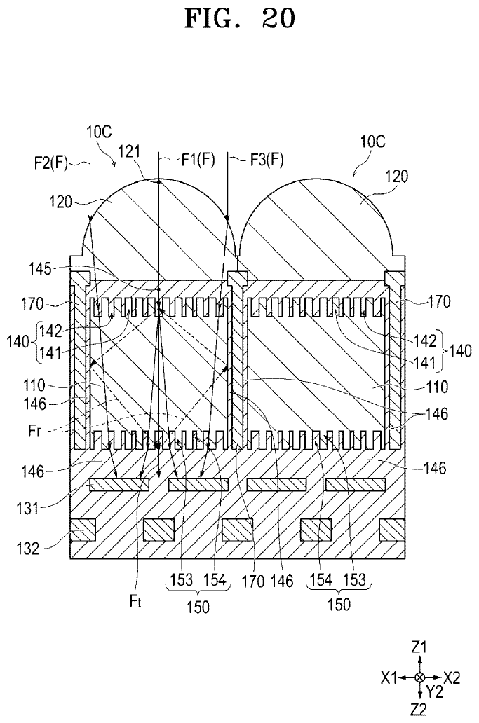

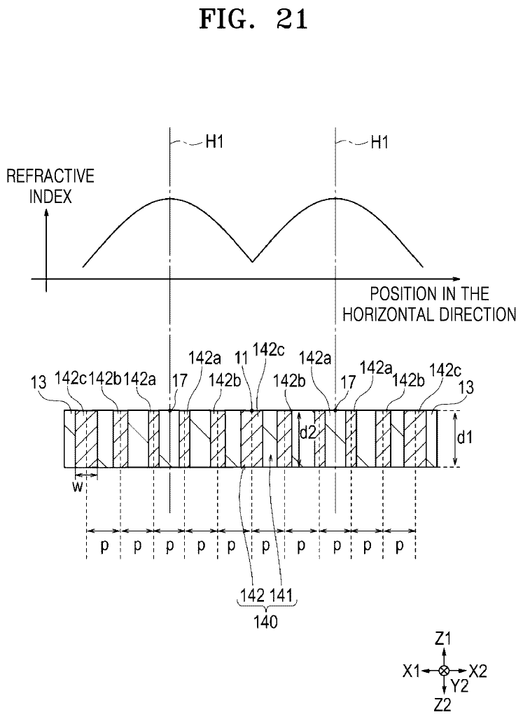

FIG. 20 is a cross-sectional view of pixels 10C according to a fourth example embodiment, taken along a stacking direction. FIG. 21 includes a graph showing the relationship between the magnitude of an average refractive index for light incident on the photoelectric conversion unit 110, and horizontal positions in the photoelectric conversion unit 110, and a schematic cross-sectional view of the first periodic structure 140 taken along a stacking direction.

In at least one of a plurality of pixels 10 included in the solid-state imaging device 1, the first periodic structure 140 may adopt a configuration in which, as illustrated in FIGS. 20 and 21, the first layers 141 and the second layers 142 are arranged such that, in intermediate regions 17 between the pixel central portion 11 and the pixel peripheral portion 13, the volume proportions of the first layers 141 are greater than the volume proportions of the second layers 142, and the volume proportions of the first layers 141 decrease from the intermediate region 17 toward the pixel central portion 11 and the pixel peripheral portion 13.

In the example illustrated in FIG. 21, one intermediate region 17 is set between the pixel central portion 11 in the horizontal direction and the pixel peripheral portion 13 that is located on one side (left) in the horizontal direction. In addition, in this example, one intermediate region 17 is set between the pixel central portion 11 in the horizontal direction and the pixel peripheral portion 13 located on the other side (right) in the horizontal direction.

As described above, because, in the first periodic structure 140, the volume proportions of the first layers 141 in the intermediate region 17 are greater than the volume proportions of the second layers 142 in the intermediate region 17, and the volume proportions of the first layers 141 decrease from the intermediate region 17 toward the pixel central portion 11 and the pixel peripheral portion 13, the average refractive index in the horizontal direction is the largest at positions corresponding to two intermediate regions 17, as shown in the graph of FIG. 21.

In the pixel 10C including the first periodic structure 140 configured as described above, even in a case in which, for example, the first wiring layers 131 arranged on the Z2 side of the photoelectric conversion unit 110 are arranged not to overlap with the central portion 121 of the on-chip lens 120 as illustrated in FIG. 20 (in a case in which the first wiring layer 131 is arranged at a position shifted in the horizontal direction from the central portion 121 of the on-chip lens 120), the incident light F1 passing through the pixel central portion 11 (the central portion 121 of the first periodic structure 140), and other incident lights F2 and F3 may be collected from their positions in the two intermediate regions 17, onto each of the first wiring layers 131 arranged at certain intervals in the horizontal direction. Thus, the pixel 10C may effectively prevent the occurrence of color mixing even in a case in which it has a stack structure in which the first wiring layers 131 are arranged not to overlap with the central portion 121 of the on-chip lens 120.

In addition, in the present embodiment, when installing two intermediate regions 17 where the refractive index of one first periodic structure 140 is the largest, as illustrated in FIG. 21, the widths w of the second layers 142 may be set to increase from the intermediate regions 17 toward the pixel central portion 11, and may also be set to increase from the intermediate regions 17 toward the pixel peripheral portion 13.

### Fifth Embodiment

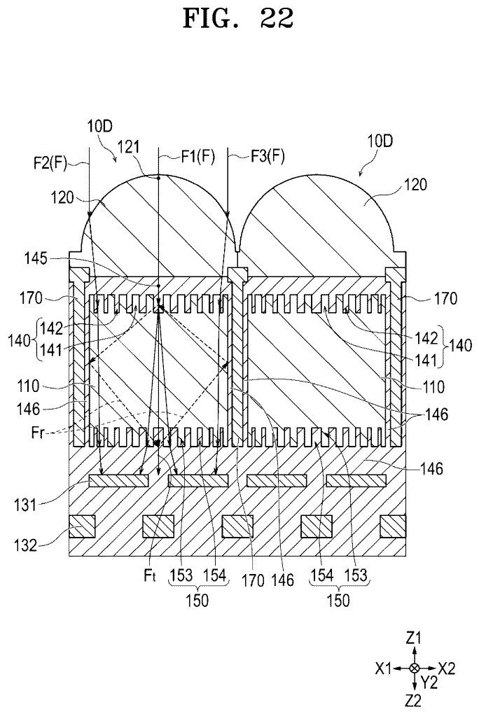

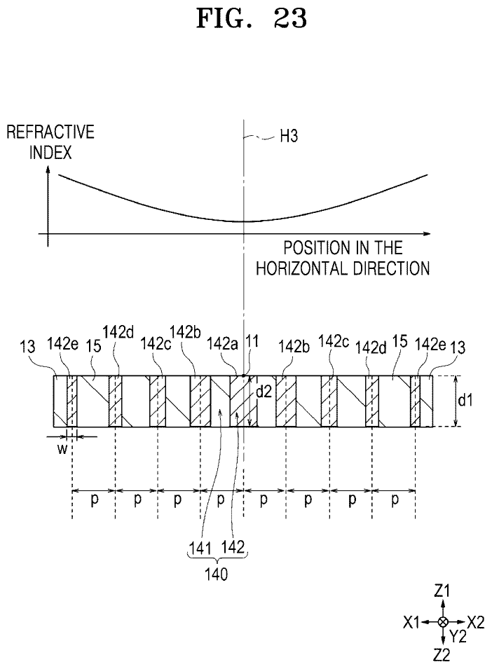

FIG. 22 is a cross-sectional view of pixels 10D according to a fifth example embodiment, taken along a stacking direction. FIG. 23 includes a graph showing the relationship between the magnitude of an average refractive index for light incident on the photoelectric conversion unit 110, and horizontal positions in the photoelectric conversion unit 110, and a schematic cross-sectional view of the first periodic structure 140 taken along a stacking direction.

In at least one of a plurality of pixels 10D included in the solid-state imaging device 1, the first periodic structure 140 may adopt a configuration in which, as illustrated in FIGS. 22 and 23, the first layers 141 and the second layers 142 are arranged such that, in proximity regions 15 close to the pixel peripheral portion 13, the volume proportions of the first layers 141 is greater than the volume proportions of the second layers 142, and the volume proportions of the first layers 141 decrease from the pixel peripheral portion 13 toward the pixel central portion 11.

The first periodic structure 140 may be configured such that, in the proximity regions 15 close to the pixel peripheral portion 13, the volume proportions of the first layers 141 are greater than the volume proportions of the second layers 142, and the volume proportions of the first layers 141 decrease from the pixel peripheral portion 13 toward the pixel central portion 11. Thus, in the first periodic structure 140, the average refractive index may be the smallest at a position corresponding to the pixel central portion 11, as shown in the graph of FIG. 23. In addition, an imaginary line H3 in the graph of FIG. 19 indicates a position in the first periodic structure 140 where the refractive index is the smallest (the same position as the pixel central portion 11).

In the pixel 10D including the first periodic structure 140 configured as described above, even in a case in which, for example, the first wiring layers 131 arranged on the Z2 side of the photoelectric conversion unit 110 are arranged not to overlap with the central portion 121 of the on-chip lens 120 as illustrated in FIG. 22, the incident light F1 passing through the pixel central portion 11 (the central portion 121 of the first periodic structure 140), and other incident lights F2 and F3 may be collected from their positions in the two intermediate regions 17, onto each of the first wiring layers 131 arranged at certain intervals in the horizontal direction. Thus, the pixel 10D may effectively prevent the occurrence of color mixing even in a case in which it has a stack structure in which the first wiring layers 131 are arranged not to overlap with the central portion 121 of the on-chip lens 120.

In addition, in the present embodiment, when the refractive index of a region corresponding to the pixel central portion 11 is the smallest and the refractive index of two regions corresponding to the pixel peripheral portion 13 is the largest, the widths w of the second layers 142 are set to decrease from the pixel central portion 11 toward the pixel peripheral portion 13, as illustrated in FIG. 23. The period p may be set to have a certain length in the horizontal direction of the first periodic structure 140.

The solid-state imaging device according to the inventive concept has been described through a plurality of embodiments and a plurality of modified examples, but the inventive concept is not limited to the descriptions provided herein and may be appropriately modified.

For example, in the third to fifth embodiments, examples of pixels each including a first periodic structure and a second periodic structure are provided, but the pixels may be configured to include only the first periodic structure. In addition, the cross-sectional shapes in the stacking direction or the arrangement in plan view of each layer of the first periodic structure and/or each layer of the second periodic structure according to the first to fifth embodiments may be configured by arbitrarily adopting and combining those of modified examples 1 to 8.

While the inventive concept has been particularly shown and described with reference to embodiments thereof, it will be understood that various changes in form and details may be made therein without departing from the spirit and scope of the following claims.

What is claimed is:

1. A solid-state imaging device comprising a pixel array comprising a plurality of pixels,
wherein each of the plurality of pixels comprises:
a photoelectric conversion unit configured to convert light into an electric charge;
an on-chip lens installed on one side of the photoelectric conversion unit;
wiring layers installed on another side of the photoelectric conversion unit; and
a first periodic structure that is installed on the one side of the photoelectric conversion unit and has periodicity in a horizontal direction that is perpendicular to a stacking direction of the photoelectric conversion unit,
wherein the first periodic structure comprises a plurality of first layers and a plurality of second layers that have refractive indices lower than refractive indices of the plurality of first layers, and
wherein in at least one of the plurality of pixels, the first layers and the second layers of the first periodic structure are arranged such that volume proportions of the first layers in a pixel central portion are greater than volume proportions of the second layers in the pixel central portion, and the volume proportions of the first layers decrease from the pixel central portion toward a pixel peripheral portion in the horizontal direction.

2. The solid-state imaging device of claim 1,
wherein widths of the second layers in the horizontal direction are different from each other, and
wherein the first periodic structure is configured such that the volume proportions of the first layers decrease from the pixel central portion toward the pixel peripheral portion.

3. The solid-state imaging device of claim 1,
wherein depths of the second layers in the stacking direction are different from each other, and
wherein the first periodic structure is configured such that the volume proportions of the first layers decrease from the pixel central portion toward the pixel peripheral portion.

4. The solid-state imaging device of claim 1, wherein a period of the first periodic structure is set to a certain value based on a wavelength and an angle of incidence of light received by the photoelectric conversion unit, and comprises a length that is less than the wavelength of the received light, and enables generation of diffracted light in the photoelectric conversion unit.

5. The solid-state imaging device of claim 1,
wherein depths of the first layers and depths of the second layers in the stacking direction are equal to a wavelength of light received by the photoelectric conversion unit, and
wherein a thickness of the photoelectric conversion unit is greater than the depths of the first layers and the depths of the second layers.

6. The solid-state imaging device of claim 1,
wherein the photoelectric conversion unit is covered at least in part by a dielectric layer having a refractive index lower than the refractive indices of the first layers, and
wherein a period of the first periodic structure comprises a length that enables diffracted light, which is generated in the photoelectric conversion unit, to be totally reflected at a boundary between the photoelectric conversion unit and the dielectric layer.

7. The solid-state imaging device of claim 1, wherein a wiring layer, which is arranged at a position closest to the photoelectric conversion unit in the stacking direction, of the wiring layers has a reflective structure that reflects light transmitted through the photoelectric conversion unit.

8. The solid-state imaging device of claim 1,
wherein a position where a volume proportion of a first layer of the first layers of the first periodic structure is largest is arranged at a position corresponding to a position of a central portion of the on-chip lens in the horizontal direction, and
wherein the central portion of the on-chip lens is arranged at a certain position between the pixel central portion and the pixel peripheral portion, in correspondence with an angle of incidence of light received by the photoelectric conversion unit.

9. The solid-state imaging device of claim 1, wherein, in at least one of the plurality of pixels, the first layers and the second layers of the first periodic structure are arranged such that, in an intermediate region between the pixel central portion and the pixel peripheral portion, the volume proportions of the first layers are greater than the volume proportions of the second layers, and the volume proportions of the first layers decrease from the intermediate region toward the pixel central portion and the pixel peripheral portion.

10. The solid-state imaging device of claim 1, wherein, in at least one of the plurality of pixels, the first layers and the second layers of the first periodic structure are arranged such that, in a proximity region close to the pixel peripheral portion, the volume proportions of the first layers are greater than the volume proportions of the second layers, and the volume proportions of the first layers decrease from the pixel peripheral portion toward the pixel central portion.

11. The solid-state imaging device of claim 1,
wherein the photoelectric conversion unit comprises a plurality of photoelectric conversion units, and
wherein the plurality of the photoelectric conversion units are separated from each other by an insulating film.

12. The solid-state imaging device of claim 1,
wherein the photoelectric conversion unit comprises a plurality of photoelectric conversion units,
wherein the plurality of the photoelectric conversion units are separated from each other by a fixed charge film, and
wherein the fixed charge film comprises an oxide film or a nitride film comprising at least one metal element from among hafnium (Hf), aluminum (Al), zirconium (Zr), tantalum (Ta), and titanium (Ti).

13. A solid-state imaging device comprising a pixel array comprising a plurality of pixels,
wherein each of the plurality of pixels comprises:
a photoelectric conversion unit configured to convert light into an electric charge;
an on-chip lens installed on one side of the photoelectric conversion unit;
a wiring layer installed on another side of the photoelectric conversion unit; and
a first periodic structure that is installed on the one side of the photoelectric conversion unit and has periodicity in a horizontal direction that is perpendicular to a stacking direction of the photoelectric conversion unit,
wherein the first periodic structure comprises a plurality of first layers and a plurality of second layers that have refractive indices lower than refractive indices of the plurality of first layers,
wherein in at least one of the plurality of pixels, the first layers and the second layers of the first periodic structure are arranged such that volume proportions of the first layers in a pixel central portion are greater than volume proportions of the second layers in the pixel central portion, and the volume proportions of the first layers decrease from the pixel central portion toward a pixel peripheral portion in the horizontal direction,
wherein the pixel comprising the first periodic structure further comprises a second periodic structure that is installed on the one side of the photoelectric conversion unit and has periodicity in the horizontal direction, and
wherein the second periodic structure comprises a plurality of third layers having refractive indices equal to the refractive indices of the first layers, and a plurality of fourth layers having refractive indices equal to the refractive indices of the second layers.

14. The solid-state imaging device of claim 13, wherein the second periodic structure has periodicity that is identical to the periodicity of the first periodic structure.

15. The solid-state imaging device of claim 13,
wherein distribution of the volume proportions of the first layers in the first periodic structure is identical to distribution of volume proportions of the third layers in the second periodic structure, and
wherein distribution of the volume proportions of the second layers in the first periodic structure is identical to distribution of volume proportions of the fourth layers in the second periodic structure.

16. The solid-state imaging device of claim 13, wherein at least one of the first periodic structure and the second periodic structure is configured based on a wavelength and an angle of incidence of light received by the photoelectric conversion unit, such that at least one of the volume proportions of the first layers and the second layers and volume proportions of the third layers and the fourth layers are different from each other.

17. The solid-state imaging device of claim 13, wherein at least one of a period of the first periodic structure and a period of the second periodic structure in a pixel array central portion differs from that in a pixel array peripheral portion.

18. A solid-state imaging device comprising a pixel array comprising a plurality of pixels,
wherein each of the plurality of pixels comprises:
a photoelectric conversion unit configured to convert light into an electric charge;
an on-chip lens installed on one side of the photoelectric conversion unit;
a wiring layer installed on another side of the photoelectric conversion unit; and
a first periodic structure that is installed on the one side of the photoelectric conversion unit and has periodicity in a horizontal direction that is perpendicular to a stacking direction of the photoelectric conversion unit,
wherein the first periodic structure comprises a plurality of first layers and a plurality of second layers that have refractive indices lower than refractive indices of the plurality of first layers, and
wherein in at least one of the plurality of pixels, depths of the second layers of the first periodic structure are equal to each other, and widths of the second layers increase from a pixel central portion toward a pixel peripheral portion.

19. The solid-state imaging device of claim 18, wherein the first layers comprise any one of silicon (Si), germanium (Ge), and indium gallium arsenide (InGaAs).

20. The solid-state imaging device of claim 18, wherein the second layers comprise any one of silicon dioxide (SiO₂), silicon nitride (SiN), aluminum oxide (AlO), tantalum oxide (TaO), titanium nitride (TiN), and titanium oxide (TiO).
